(19) United States
(12) Patent Application Publication
(10) Pub. No.: US 2026/0235645 A1
(43) Pub. Date: Aug. 13, 2026

(54) TESTING DEVICE AND ITS POGO PROBE DEVICE

(71) Applicants: GLOBAL UNICHIP CORPORATION, HSINCHU CITY (TW); TAIWAN SEMICONDUCTOR MANUFACTURING COMPANY, LTD., Hsinchu (TW)

(72) Inventors: Chih-Chieh LIAO, HSINCHU CITY (TW); Yu-Min SUN, HSINCHU CITY (TW); Chih-Feng CHENG, HSINCHU CITY (TW)

(21) Appl. No.: 19/079,490

(22) Filed: Mar. 14, 2025

(30) Foreign Application Priority Data
Feb. 10, 2025 (TW) 114104913

(51) Int. Cl. G01R 1/067

(52) U.S. Cl. CPC G01R 1/06722

(57) ABSTRACT

A pogo probe device provided includes a probe needle body, a compression spring and a plunger. The probe needle body is provided with a tubular channel therein. The compression spring is received within the tubular channel. The plunger includes a plunger body, a probe tip, an inclined surface and a scraping portion. The plunger body is slidably inserted into one end of the probe needle body to abut against the compression spring. The probe tip is located at one end of the plunger body opposite to the compression spring. The probe tip is located at another end of the plunger body opposite to the compression spring. The inclined surface is connected to the probe tip and an outer lateral side of the plunger body. The scraping portion includes a plurality of parallel sawtoothed rows arranged on the inclined surface along the inclined surface.

### RELATED APPLICATIONS

This application claims priority to Taiwanese Application Serial Number 114104913, filed Feb. 10, 2025, which are herein incorporated by reference.

### BACKGROUND

### Field of Invention

The present disclosure relates to a pogo probe device. More particularly, the present disclosure relates to a pogo probe device which is able to improve tin slag residue, and a testing device having the same.

### Description of Related Art

Generally, when a device under test (e.g., a semiconductor package chip, hereinafter referred to as DUT) is electrically tested with a probe card, a plurality of probes of the probe card are collectively in contact with the DUT for electrically testing the DUT.

However, each of the probes which may accumulated residues (e.g., solder balls or slag) at the needle tip thereof is needed to be scraped or cleaned frequently. Otherwise, if the residues are overly accumulated, it will increase the resistance value of the probes and reduce the conductive efficiency of the probes, thereby affecting the test results of the probe card.

Therefore, the above-mentioned technology apparently is still with inconvenience and defects and needed to be further developed. Hence, how to develop a solution to improve the foregoing deficiencies and inconvenience is an important issue that relevant persons engaged in the industry are currently unable to delay.

### SUMMARY

One aspect of the present disclosure is to provide a testing device and its pogo probe device for solving the difficulties mentioned above in the prior art.

In one embodiment of the present disclosure, a pogo probe device includes a probe needle body, a compression spring and a first plunger. The probe needle body is provided with a tubular channel therein. The compression spring is received within the tubular channel. The first plunger includes a plunger body, a probe tip, an inclined surface and a scraping portion. The plunger body is slidably inserted into one end of the probe needle body to abut against the compression spring within the probe needle body. The probe tip is located at one end of the plunger body opposite to the compression spring. The inclined surface is connected to the probe tip and an outer lateral side of the plunger body. The scraping portion includes a plurality of sawtooth rows which are arranged in parallel on the inclined surface, and each of the sawtooth rows extends along a long axis direction of the inclined surface.

In one embodiment of the present disclosure, a testing device includes a pressing member, a circuit board, a probe holder and the pogo probe device described above. The pressing member is capable of raising and lowering. The circuit board is disposed below the pressing member, and provided with at least one electrical contact. The probe holder includes a base located on the circuit board, and a slot recessed on a top surface of the base for placing an electrical component. The electrical component includes a package body and at least one pin, the pin includes a front section, a rear section and a connecting section, the front section extends from one side of the package body and provided with different heights from the rear section, and the connecting section is connected to the front section and the rear section, and a lower arc surface is formed by the rear section and the connecting section. The aforementioned pogo probe device is inserted into a recess bottom of the slot, electrically connected to the electrical contact, and positioned to vertically align the lower arc surface of the pin of the electrical component. When the pressing member contacts to press the electrical component in the slot, the scraping portion of the pogo probe device contacts and slides through the lower curved surface of the pin.

Thus, through the construction of the embodiments above, the pogo probe device of the testing device of the disclosure can slide and scrape the lower curved surface of the corresponding pin of the electrical component during each test, provide a self-cleaning function (i.e. automatically removing tin slag), thereby reducing the resistance value of the probe, improving the conductive efficiency of the probe and the test results of the probe card.

The above description is merely used for illustrating the problems to be resolved, the technical methods for resolving the problems and their efficacies, etc. The specific details of the present disclosure will be explained in the embodiments below and related drawings.

### BRIEF DESCRIPTION OF THE DRAWINGS

The disclosure can be more fully understood by reading the following detailed description of the embodiment, with reference made to the accompanying drawings as follows.

FIG. 1A is a perspective view of a pogo probe device according to one embodiment of the present disclosure.

FIG. 1B is a longitudinal cross-sectional view of the pogo probe device of FIG. 1A along a vertical direction.

FIG. 2 is a schematic diagram of an area shown in FIG. 1A.

FIG. 3 is a cross-sectional view of FIG. 2 along a line AA.

FIG. 4 is a partial cross-sectional view of the first plunger according to one embodiment of the present disclosure, wherein a cross-sectional direction of FIG. 4 is the same as that of FIG. 3.

FIG. 5 is an exploded view of a testing device according to one embodiment of the present disclosure.

FIG. 6 is an operation diagram of the pogo probe device of FIG. 5 for a pin of an electrical component.

### DETAILED DESCRIPTION

Reference will now be made in detail to the present embodiments of the present disclosure, examples of which are illustrated in the accompanying drawings. Wherever possible, the same reference numbers are used in the drawings and the description to refer to the same or like parts. According to the embodiments, it will be apparent to those skilled in the art that various modifications and variations can be made to the structure of the present disclosure without departing from the scope or spirit of the present disclosure.

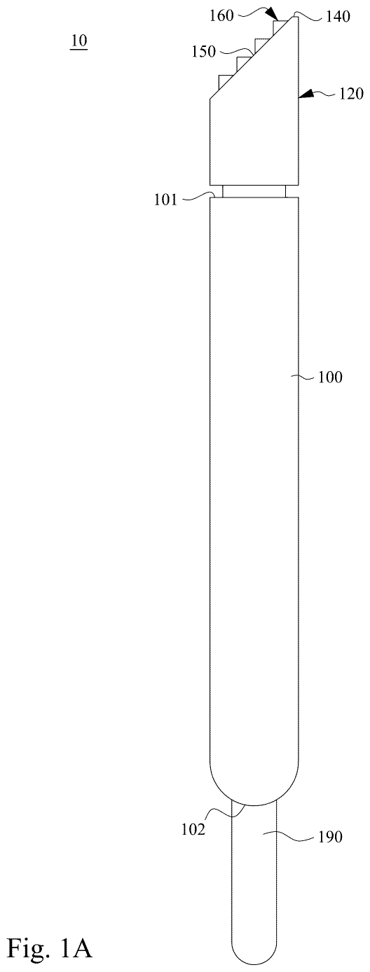

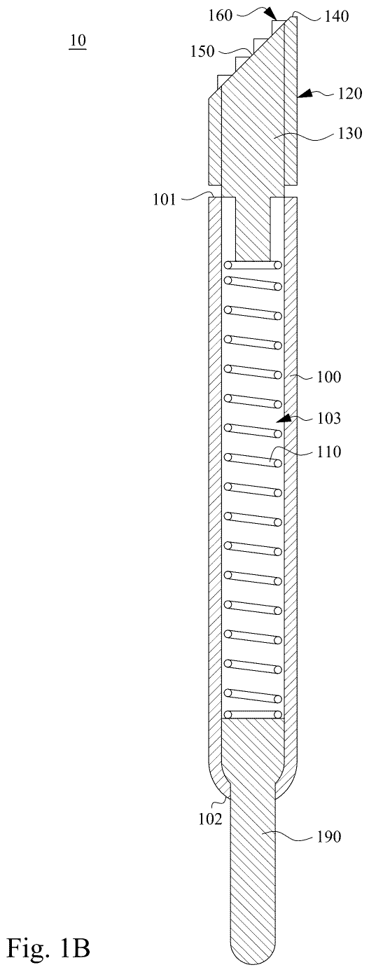

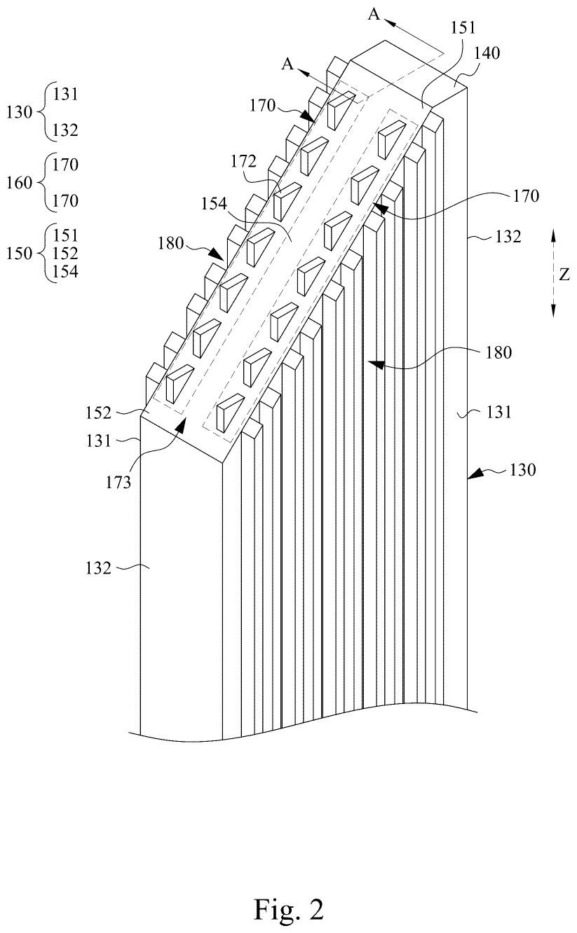

Reference is now made to FIG. 1A to FIG. 3 in which FIG. 1A is a perspective view of a pogo probe device 10 according to one embodiment of the present disclosure, FIG. 1B is a longitudinal cross-sectional view of the pogo probe device 10 of FIG. 1A along a vertical direction, and FIG. 2 is a schematic diagram of an area shown in FIG. 1A. FIG. 3 is a cross-sectional view of FIG. 2 along a line AA. As shown in FIG. 1A to FIG. 3, in the embodiment, the pogo probe device 10 includes a probe needle body 100, a compression spring 110, a first plunger 120 and a second plunger 190. The probe needle body 100 is in a shape of a straight tube, and the probe needle body 100 includes a first end 101, a second end 102 and a tubular channel 103 therein. The first end 101 and the second end 102 are opposite to each other. The tubular channel 103 is formed in the probe needle body 100, and coaxial with the probe needle body 100, and respectively connected to the first end 101 and the second end 102. The compression spring 110 is confined within the tubular channel 103. The first plunger 120 is slidably inserted into the first end 101 of the probe needle body 100 to abut against the compression spring 110 within the tubular channel 103, so that the first plunger 120 can be resilient after being pressed on the probe needle body 100. The second plunger 190 is slidably inserted into the second end 102 of the probe needle body 100 to abut against the compression spring 110 within the tubular channel 103, so that the second plunger 190 can be resilient after being pressed on the probe needle body 100.

More specifically, the first plunger 120 includes a plunger body 130, a probe tip 140, an inclined surface 150 and a scraping portion 160. The plunger body 130 is linear and slidably inserted into the first end 101 of the probe needle body 100. One end of the plunger body 130 abuts against the compression spring 110 in the tubular channel 103, and the probe tip 140 is located at the other end of the plunger body 130 (i.e., the opposite end of the compression spring 110). More specifically, the plunger body 130 includes two opposite first outer lateral sides 131 and two opposite second outer lateral sides 132. Each of the first outer lateral sides 131 is connected to the inclined surface 150, the probe tip 140 and the second outer lateral sides 132, respectively. The inclined surface 150 is inclined relative to the plunger body 130. The long axis direction 153 of the inclined surface 150 and the long axis direction 153 (e.g., the Z axis) of the probe needle body 100 (i.e., the plunger body 130) have an included angle θ which is 135° to 145°, for example. The inclined surface 150 is rectangular, and two opposite ends of the inclined surface 150 are respectively connected to the probe tip 140 and one of the second outer lateral sides 132 (i.e., the shorter one of the second outer lateral sides 132) of the plunger body 130. The scraping portion 160 includes a plurality (e.g., 2 to 3) of sawtooth rows 170 which are arranged in parallel, and each of the sawtooth rows 170 extends along a long axis direction 153 of the inclined surface 150. A slag discharge channel 173 is defined between any two adjacent ones of the sawtooth rows 170. The sawtooth rows 170 are arranged on the inclined surface 150. The sawtooth rows 170 are spaced apart from the first outer lateral sides 131 and the second outer lateral side 132, and the sawtooth rows 170 and the corresponding first outer lateral side 131 are kept spaced.

In the embodiment, each of the sawtooth rows 170 includes a plurality of sharp tooth pieces 172. The sharp tooth pieces 172 of each of the sawtooth rows 170 are arranged in a single row along the long axis direction 153 of the inclined surface 150, and the sharp tooth pieces 172 are separated from each other and arranged at intervals along the long axis direction 153 of the inclined surface 150. A tip of each of the sharp tooth pieces 172 extends along the normal direction L of the inclined surface 150. Also, these the sharp tooth pieces 172 and the inclined surface 150 can be collectively referred to as sawtooth slope.

In this embodiment, furthermore, the inclined surface 150 is sequentially divided into an upper inclined surface area 151, a middle section area 154 and a lower inclined surface area 152. The middle section area 154 is located between the upper inclined surface area 151 and the lower inclined surface area 152, and the scraping portion 160 (i.e., sawtooth rows 170) is only located within the middle section area 154. The upper inclined surface area 151 is respectively connected to the middle section area 154 and the probe tip 140, and the lower inclined surface area 152 is respectively connected to the middle section area 154 and the shorter one of the second outer lateral sides 132 of the plunger body 130.

In addition, the plunger body 130 is further provided with two linear grooved structures 180, and the linear grooved structures 180 are respectively formed on two external surfaces of the plunger body 130 which are opposite to each other. For example, the linear grooved structures 180 are respectively formed on the first outer lateral sides 131 of the plunger body 130. However, the present disclosure is not limited thereto. In other embodiments, the inclined surface 150 may also be triangular; the long axis directions (refer to the long axis direction 153) of these sawtooth rows 170 may also intersect with each other; these sharp tooth pieces 172 may also be directly connected to each other along the long axis direction 153 of the inclined surface 150; each of the sawtooth rows 170 may also be directly connected to the corresponding first outer lateral sides 131 and these second outer lateral sides 132; or/and the tip of each of the sharp tooth pieces 172 may also extend toward the long axis direction (e.g., the Z axis) of the plunger body 130.

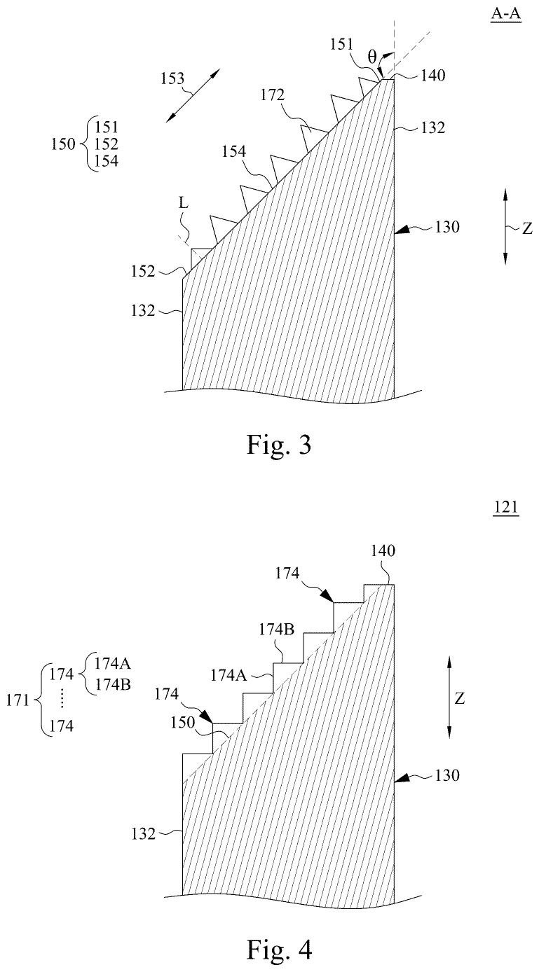

FIG. 4 is a partial cross-sectional view of the first plunger 121 according to one embodiment of the present disclosure, wherein a cross-sectional direction of FIG. 4 is the same as that of FIG. 3. As shown in FIG. 3 and FIG. 4, the first plunger 121 of FIG. 4 and the first plunger 120 of FIG. 3 are substantially the same, except that each of the sawtooth rows 170 is in a step shape, and the sharp tooth pieces 172 of each of the sawtooth row 171 are directly connected in sequence. More specifically, each of the sharp tooth pieces 174 includes a first step surface 174A and a second step surface 174B which are connected to each other, and the first step surface 174A is orthogonal to the second step surface 174B and the first step surface 174A is parallel to the long axis direction (e.g., the Z axis) of the plunger body 130 (i.e., probe needle body 100). The first step surface 174A of each of the sharp tooth pieces 174 is connected to the second step surface 174B of the adjacent one of the sharp tooth pieces 174. Similarly, the second step surface 174B is adjacent to the first step surface 174A of the adjacent one of the sharp tooth pieces 174. It is noted, since the sharp tooth pieces 174 of each of the sawtooth row 171 are directly connected as a whole, a stronger structural strength can be provided and foreign objects can be prevented from being left between the sharp tooth pieces 174.

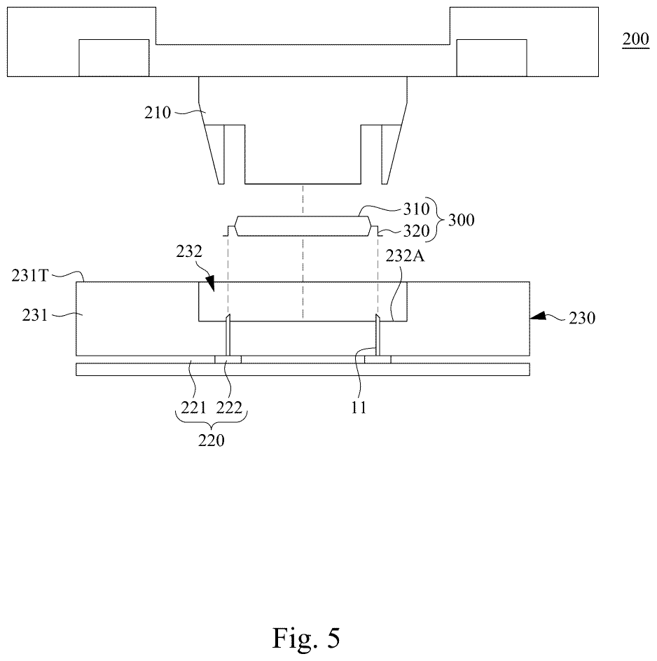

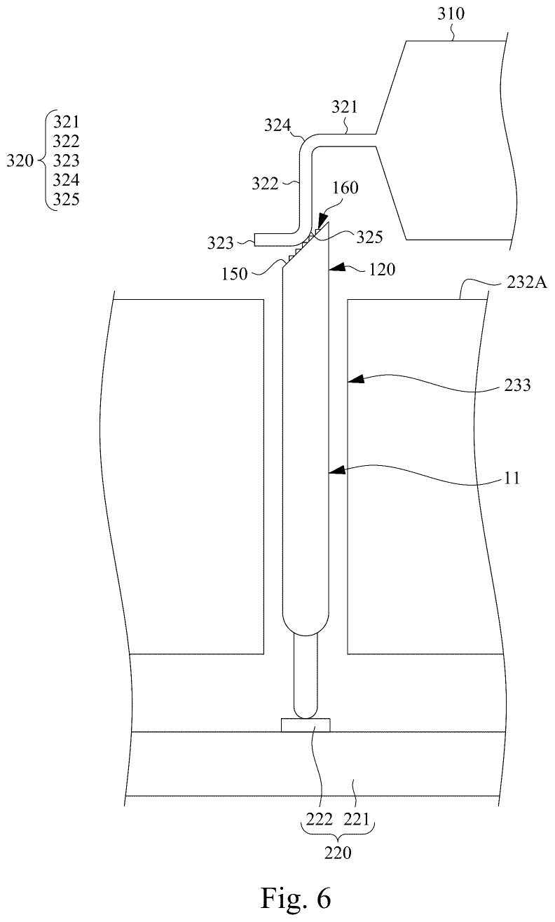

FIG. 5 is an exploded view of a testing device 200 according to one embodiment of the present disclosure. FIG. 6 is an operation diagram of the pogo probe device 11 of FIG. 5 for a pin 320 of an electrical component 300. As shown in FIG. 5 and FIG. 6, a testing device 200 is suitable for performing electrical testing on an electrical component 300, and the testing device 200 includes a pressing member 210, a circuit board 220, a probe holder 230 and a plurality of pogo probe devices 11. The pressing member 210 is liftably moved for raising and lowering. The circuit board 220 is disposed below the pressing member 210, and provided with a board body 221 and a plurality of electrical contacts 222 arranged on one surface of the board body 221 at intervals. The probe holder 230 includes a base 231 and a slot 232. The base 231 is located on the circuit board 220, and positioned between the pressing member 210 and the circuit board 220. The slot 232 is recessed on a top surface 231T of the base 231 for placing the electrical component 300. These pogo probe devices 11 are spaced distributed within the slot 232, that is, in this embodiment, each of the pogo probe devices 11 is vertically inserted into one of the probe holes 233 formed on the recess bottom 232A of the slot 232, and electrically connects one of the electrical contacts 222 and one of the pins 320 of the electrical component 300, so that the electrical component 300 and the circuit board 220 are electrically connected. The pogo probe devices 11 of the testing device 200 may use the pogo probe devices 11 of the above-mentioned embodiments.

In this embodiment, for example, the electrical component 300 includes a package body 310 and a plurality of pins 320. The package body 310 is provided with a rectangular outline. The pins 320 are spaced arranged on each of sides (e.g., four sides) of the package body 310, so that the pins 320 of the electrical component 300 respectively extend outwards from the package body 310. Each of the pins 320 of the electrical component 300 is in a Z-shape, and each of the pins 320 includes a front section 321, a rear section 323 and a connecting section 322. The front section 321 extends from one side of the package body 310 and provided with different heights from the rear section 323. The front section 321 extends outwards from one side of the package body 310 and provided with different heights from the rear section 323. The connecting section 322 is connected to the front section 321 and the rear section 323, and an upper arc surface 324 is formed by the front section 321 and the connecting section 322, and a lower arc surface 325 is formed by the rear section 323 and the connecting section 322. The lower arc surface 325 has a high curvature (e.g., R<0.2 mm).

In the present embodiment, these pogo probe devices 11 are designed to be specifically arranged within the slot 232 so that each of the pogo probe devices 11 is exactly aligned vertically with the lower arc surface 325 of one of the pins 320 of the electrical component 300 along the Z-axis direction, rather than the rear section 323 thereof. In other words, the orthographic projection of the lower arc surface 325 of one of the pins 320 of the electrical component 300 onto the corresponding pogo probe device 11 is exactly located on the inclined surface 150 (i.e., the scraping portion 160). When the electrical component 300 is vertically placed in the slot 232, the scraping portion 160 of each of the corresponding pogo probe device 11 can just contact the lower arc surface 325 of the corresponding pin 320.

In this way, when the pressing member 210 contacts to press against the electrical component 300 within the slot 232, the scraping portion 160 of the pogo probe device 11 can contact and slide through the lower arc surface 325 of the pin 320 along the arc contour of the lower arc surface 325, thereby having a self-cleaning function which is able to automatically remove solder slag and automatically scrape off the residue (e.g., solder balls or solder slag) on the lower arc surface 325 of the pin 320.

It is noted, since the scraping portion 160 of the first plunger 120 of the pogo probe device 11 is located on the inclined surface 150, when the scraping portion 160 of the pogo probe device 11 scrapes the residue (e.g., solder balls or solder slag) on the lower arc surface 325 of the corresponding pin 320, the residue (e.g., solder balls or solder slag) can be separated from the pogo probe device 11 from the inclined surface 150.

In this embodiment, the pogo probe device 11 is, for example, a coaxial pogo pin, however, the present disclosure is not limited thereto. The electrical component 300 is, for example, a Quad Flat Package (QFP), a Low Profile Quad Flat Package (LQFP), an Analog to Digital Converter (ADC), and a Digital to Analog Converter (DAC), etc. However, the present disclosure is not limited thereto.

Thus, through the construction of the embodiments above, the pogo probe device of the testing device of the disclosure can slide and scrape the lower curved surface of the corresponding pin of the electrical component during each test, provide a self-cleaning function (i.e. automatically removing tin slag), thereby reducing the resistance value of the probe, improving the conductive efficiency of the probe and the test results of the probe card.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A pogo probe device, comprising:
a probe needle body provided with a tubular channel therein;
a compression spring received within the tubular channel; and
a first plunger comprising:
a plunger body slidably inserted into one end of the probe needle body to abut against the compression spring within the probe needle body;
a probe tip located at one end of the plunger body opposite to the compression spring;
an inclined surface connected to the probe tip and an outer lateral side of the plunger body; and
a scraping portion comprising a plurality of sawtooth rows which are arranged in parallel on the inclined surface, and each of the sawtooth rows extends along a long axis direction of the inclined surface.

2. The pogo probe device of claim 1, wherein each of the sawtooth rows comprises a plurality of sharp tooth pieces arranged in a single row along the long axis direction of the inclined surface.

3. The pogo probe device of claim 2, wherein the sharp tooth pieces are directly connected one by one along the long axis direction of the inclined surface; or
the sharp tooth pieces are spaced arranged along the long axis direction of the inclined surface.

4. The pogo probe device of claim 2, wherein the inclined surface is provided with an upper inclined surface area and a lower inclined surface area,
wherein the scraping portion is located between the upper inclined surface area and the lower inclined surface area, and the upper inclined surface area is connected to the sawtooth rows and the probe tip, respectively, and the lower inclined surface area is connected to the sawtooth rows and the outer lateral side of the plunger body, respectively.

5. The pogo probe device of claim 2, wherein each of the sawtooth rows is in a step shape, and each of the sharp tooth pieces includes a first step surface and a second step surface, wherein the first step surface is orthogonal to the second step surface and parallel to the long axis direction of the probe needle body.

6. The pogo probe device of claim 1, wherein a number of the sawtooth rows is 2-3, and a slag discharge channel is defined between any two adjacent ones of the sawtooth rows.

7. The pogo probe device of claim 1, wherein the sawtooth rows are respectively connected to two external surfaces of the probe needle body which are opposite to each other.

8. The pogo probe device of claim 1, wherein the plunger body further includes two linear grooved structures, and the linear grooved structures are respectively formed on two external surfaces of the probe needle body which are opposite to each other.

9. The pogo probe device of claim 1, wherein an included angle is defined between the long axis direction of the inclined surface and the long axis direction of the probe needle body, and the included angle is 135° to 145°.

10. The pogo probe device of claim 1, further comprising:
a second plunger slidably inserted into the other end of the probe needle body to abut against the compression spring received within the tubular channel.

11. A pogo probe device, comprising:
a probe needle body provided with a tubular channel therein;
a compression spring received within the tubular channel;
a first plunger comprising:
a plunger body slidably inserted into one end of the probe needle body to abut against the compression spring within the probe needle body;
a probe tip located at one end of the plunger body opposite to the compression spring; and
a sawtooth slope comprising an inclined surface and a plurality of sharp tooth pieces, wherein the inclined surface is connected to the probe tip and one of outer lateral sides of the plunger body, and the sharp tooth pieces are arranged in sequence along a long axis direction of the inclined surface; and
a second plunger slidably inserted into the other end of the probe needle body to abut against the compression spring received within the tubular channel.

12. The pogo probe device of claim 11, wherein the sharp tooth pieces are arranged in a single row along the long axis direction of the inclined surface.

13. The pogo probe device of claim 11, wherein the sharp tooth pieces are directly connected one by one along the long axis direction of the inclined surface; or
the sharp tooth pieces are spaced arranged along the long axis direction of the inclined surface.

14. The pogo probe device of claim 11, wherein the inclined surface is provided with an upper inclined surface area and a lower inclined surface area,
wherein the sharp tooth pieces are located between the upper inclined surface area and the lower inclined surface area, and the upper inclined surface area is connected to the probe tip, and the lower inclined surface area is connected to the one of the outer lateral sides of the plunger body.

15. The pogo probe device of claim 11, wherein the sharp tooth pieces are shown in a step shape, and each of the sharp tooth pieces includes a first step surface and a second step surface, wherein the first step surface is orthogonal to the second step surface and parallel to a long axis direction of the probe needle body.

16. The pogo probe device of claim 11, wherein a slag discharge channel is defined between the sharp tooth pieces.

17. The pogo probe device of claim 11, wherein the sharp tooth pieces are respectively connected to two external surfaces of the probe needle body which are opposite to each other.

18. The pogo probe device of claim 11, wherein the plunger body further includes two linear grooved structures, and the linear grooved structures are respectively formed on two external surfaces of the probe needle body which are opposite to each other.

19. The pogo probe device of claim 11, wherein an included angle is defined between the long axis direction of the inclined surface and the long axis direction of the probe needle body, and the included angle is 135° to 145°.

20. A testing device, comprising:
a pressing member capable of raising and lowering;
a circuit board disposed below the pressing member, and provided with at least one electrical contact;
a probe holder comprising a base located on the circuit board, and a slot recessed on a top surface of the base for placing an electrical component, wherein the electrical component comprises a package body and at least one pin, the at least one pin comprises a front section, a rear section and a connecting section, the front section extends from one side of the package body and provided with different heights from the rear section, and the connecting section is connected to the front section and the rear section, and a lower arc surface is formed by the rear section and the connecting section; and
a pogo probe device of claim 1 inserted into a recess bottom of the slot, electrically connected to the at least one electrical contact, and positioned to vertically align the lower arc surface of the at least one pin of the electrical component,
wherein when the pressing member contacts to press the electrical component in the slot, the scraping portion of the pogo probe device contacts and slides through the lower curved surface of the at least one pin.
